(19) United States
(12) Patent Application Publication
(10) Pub. No.: US 2026/0121615 A1
(43) Pub. Date: Apr. 30, 2026

(54) MULTILAYER PIEZOELECTRIC SUBSTRATE NONLINEARITY IMPROVEMENT WITHIN THE STACK OF LAYERS

(71) Applicant: SKYWORKS SOLUTIONS, INC., Irvine, CA (US)

(72) Inventors: Xiangnan Pang, Irvine, CA (US); Yiliu Wang, Irvine, CA (US); Nan Wu, Irvine, CA (US)

(21) Appl. No.: 19/361,199

(22) Filed: Oct. 17, 2025

Related U.S. Application Data
(60) Provisional application No. 63/711,269, filed on Oct. 24, 2024.

(51) Int. Cl. H03H 9/25; H03H 3/08; H03H 9/02; H03H 9/64

(52) U.S. Cl. CPC H03H 9/25; H03H 3/08; H03H 9/02574; H03H 9/02818; H03H 9/6483

(57) ABSTRACT

Aspects and embodiments disclosed herein include a surface acoustic wave resonator comprising a carrier substrate, a trap-rich layer having a lower surface disposed on the upper surface of the carrier substrate, a low acoustic velocity dielectric layer a lower surface disposed on the upper surface of the trap-rich layer, and a layer of piezoelectric material having a lower surface disposed on the upper surface of the low acoustic velocity dielectric layer. A thickness of one or more of the carrier substrate, the trap-rich layer, or the low acoustic velocity dielectric layer is selected to mitigate H2 and/or H3 spurious signals generated during operation of the surface acoustic wave resonator.

### CROSS-REFERENCE TO RELATED APPLICATIONS

This application claims priority under 35 U.S.C. § 119(e) to U.S. Provisional Patent Application Serial No. 63/711,269, titled “MULTILAYER PIEZOELECTRIC SUBSTRATE NONLINEARITY IMPROVEMENT WITH THE STACK,” filed October 24, 2024, the entire content of which is incorporated herein by reference for all purposes.

### BACKGROUND

### TECHNICAL FIELD

Embodiments of this disclosure relate to acoustic wave devices having multilayer piezoelectric substrates, and to filters and electronic devices including same.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front end of a mobile telephone can include acoustic wave filters. Two acoustic wave filters can be arranged as a duplexer or a diplexer.

### SUMMARY

In accordance with one aspect, there is provided a surface acoustic wave resonator including a multilayer piezoelectric substrate. The surface acoustic wave resonator comprises a carrier substrate having an upper surface and a lower surface, a trap-rich layer having an upper surface and a lower surface, the lower surface of the trap-rich layer disposed on the upper surface of the carrier substrate, a low acoustic velocity dielectric layer having an upper surface and a lower surface, the lower surface of the low acoustic velocity dielectric layer disposed on the upper surface of the trap-rich layer, and a layer of piezoelectric material having an upper surface and a lower surface, the lower surface of the layer of piezoelectric material disposed on the upper surface of the low acoustic velocity dielectric layer, a thickness of one or more of the carrier substrate, the trap-rich layer, or the low acoustic velocity dielectric layer selected to mitigate H2 and/or H3 spurious signals generated during operation of the surface acoustic wave resonator.

In some embodiments, the lower surface of the carrier substrate is roughened.

In some embodiments, the lower surface of the carrier substrate has a roughness parameter Ra ≥ 0.2 µm.

In some embodiments, the lower surface of the trap-rich layer is roughened.

In some embodiments, the lower surface of the trap-rich layer has a roughness parameter Ra ≥ 0.2 µm.

In some embodiments, the surface acoustic wave resonator further comprises a layer of damping material disposed on the lower surface of the carrier substrate.

In some embodiments, the low acoustic velocity dielectric layer comprises silicon dioxide.

In some embodiments, the trap-rich layer comprises polysilicon.

In some embodiments, the low acoustic velocity dielectric layer has a thickness of between 1 µm and 3 µm.

In some embodiments, the trap-rich layer has a thickness of about 1 µm.

In some embodiments, the surface acoustic wave resonator is included in a filter.

In some embodiments, the filter is included in a radio frequency device module.

In some embodiments, the radio frequency device module is included in a radio frequency device.

In accordance with another aspect, there is provided a method of forming a surface acoustic wave resonator. The method comprises providing a carrier substrate having an upper surface and a lower surface, forming a trap-rich layer on the upper surface of the carrier substrate, forming a low acoustic velocity dielectric layer on an upper surface of trap-rich layer, forming a layer of piezoelectric material on an upper surface of the low acoustic velocity dielectric layer, and forming interdigital transducer electrodes on an upper surface of the layer of piezoelectric material, a thickness of one or more of the carrier substrate, the trap-rich layer, or the low acoustic velocity dielectric layer selected to mitigate H2 and/or H3 spurious signals generated during operation of the surface acoustic wave resonator.

In some embodiments, the method further comprises roughening the lower surface of the carrier substrate.

In some embodiments, the method further comprises roughening a lower surface of the trap-rich layer.

In some embodiments, the method further comprises forming a layer of damping material on the lower surface of the carrier substrate.

In some embodiments, the method further comprises forming a radio frequency filter including the surface acoustic wave resonator.

In some embodiments, the method further comprises forming a radio frequency device module including the radio frequency filter.

In some embodiments, the method further comprises forming a radio frequency electronic device including the radio frequency device module.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of a portion of a surface acoustic wave resonator having a first example of a multilayer piezoelectric substrate;

FIG. 3 is a cross-sectional view of a portion of a surface acoustic wave resonator having another example of a multilayer piezoelectric substrate;

FIG. 4 is a cross-sectional view of a portion of a surface acoustic wave resonator having another example of a multilayer piezoelectric substrate;

FIG. 5 is a cross-sectional view of a portion of a surface acoustic wave resonator having another example of a multilayer piezoelectric substrate;

FIG. 6 is a cross-sectional view of a portion of a surface acoustic wave resonator having another example of a multilayer piezoelectric substrate;

FIG. 7 is a schematic diagram of a radio frequency ladder filter;

FIG. 8 is a block diagram of one example of a filter module that can include one or more acoustic wave elements according to aspects of the present disclosure;

FIG. 9 is a block diagram of one example of a front-end module that can include one or more filter modules according to aspects of the present disclosure; and

FIG. 10 is a block diagram of one example of a wireless device including the front-end module of FIG. 9.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

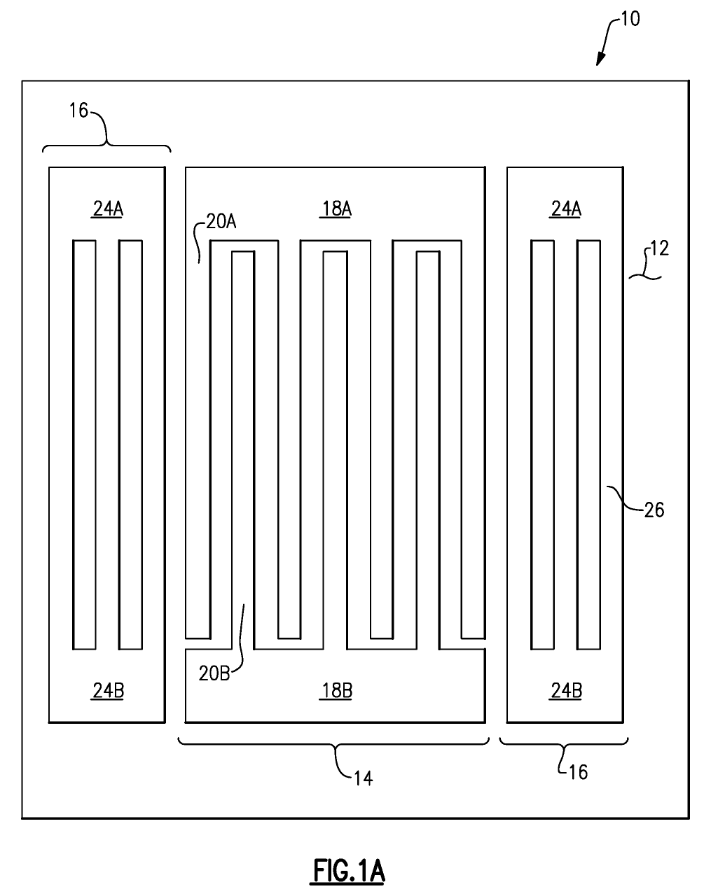

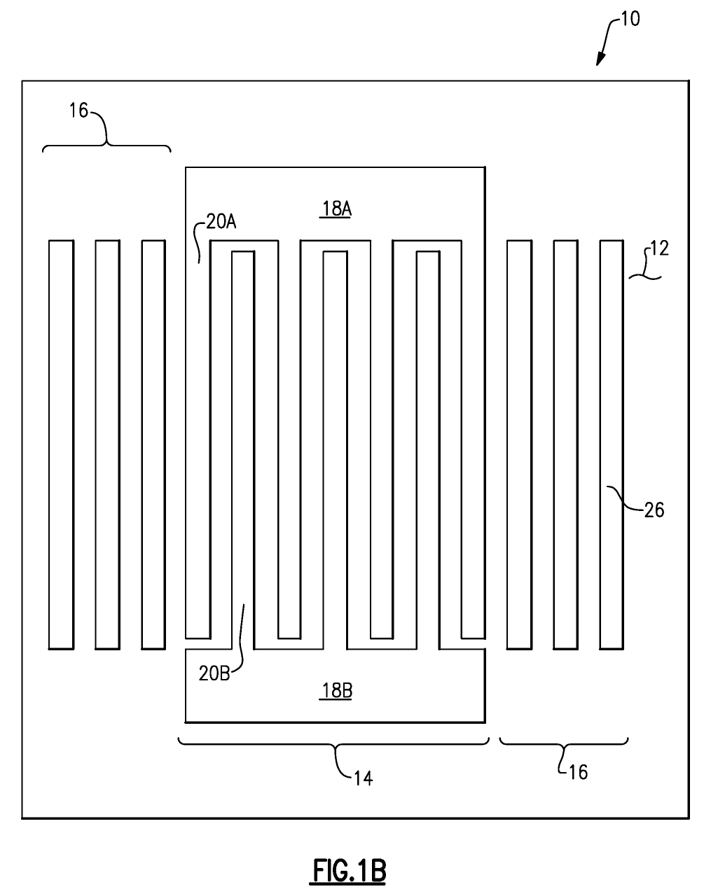

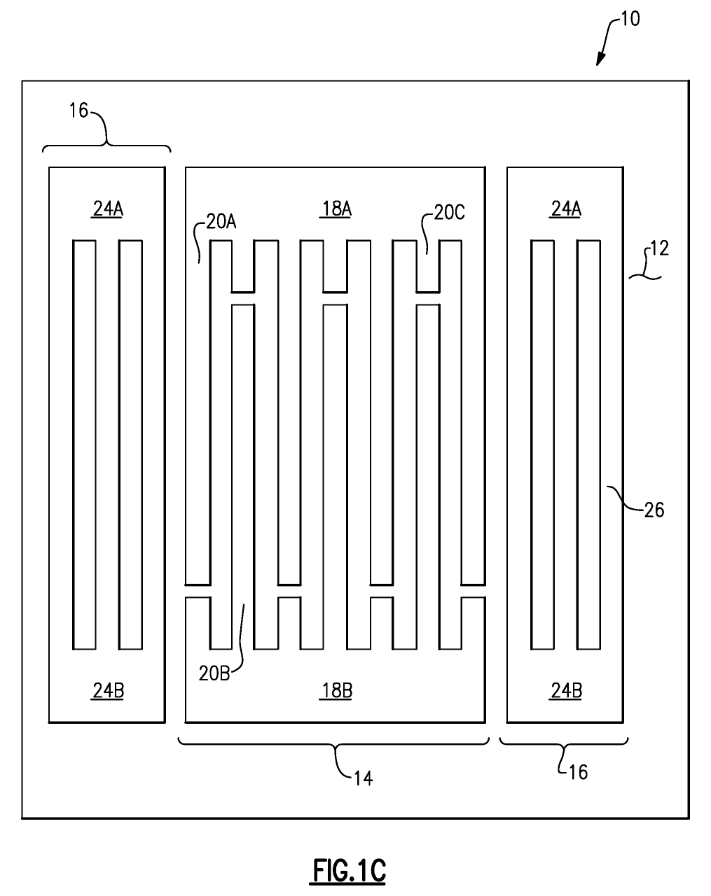

FIG. 1A is a plan view of a surface acoustic wave (SAW) resonator 10 such as might be used in a SAW filter, duplexer, diplexer, balun, etc.

Surface acoustic wave resonator 10 is formed on a piezoelectric substrate, for example, a lithium tantalate (LiTaO₃) or lithium niobate (LiNbO₃) substrate 12 and includes interdigital transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first busbar electrode 18A and a second busbar electrode 18B facing first busbar electrode 18A. The busbar electrodes 18A, 18B may be referred to herein together as busbar electrode 18. The IDT electrodes 14 further include first electrode fingers 20A extending from the first busbar electrode 18A toward the second busbar electrode 18B, and second electrode fingers 20B extending from the second busbar electrode 18B toward the first busbar electrode 18A.

The reflector electrodes 16 (also referred to as reflector gratings) each include a first reflector busbar electrode 24A and a second reflector busbar electrode 24B (collectively referred to herein as reflector busbar electrode 24) and reflector fingers 26 extending between and electrically coupling the first busbar electrode 24A and the second busbar electrode 24B.

In other embodiments disclosed herein, as illustrated in FIG. 1B, the reflector busbar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite busbar electrode 18A, 18B than the respective electrode finger 20A, 20B with which it is aligned.

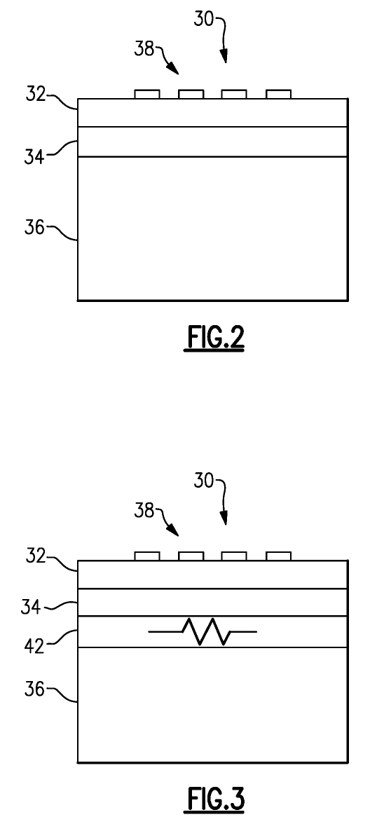

FIG. 2 is a partial cross-sectional view of an acoustic wave resonator 30 having a multilayer piezoelectric substrate including a layer 32 of piezoelectric material, for example, lithium tantalate or lithium niobate, a dielectric material layer 34, for example, silicon dioxide, on which the layer 32 of piezoelectric material is disposed, and a carrier substrate 36 on which the dielectric material layer 34 is disposed. IDT and reflector electrodes, indicated collectively at 38, having configurations such as illustrated in any of FIGS. 1A-1C, may be disposed on the upper surface of the layer 32 of piezoelectric material. The carrier substrate 36 may be formed of, for example, Si. Advantages of forming an acoustic wave resonator 30 with a multiplayer piezoelectric substrate as illustrated in FIG. 2 is that the Si material for the carrier substrate 36 is widely available and easily processed by techniques developed in the semiconductor industry. A disadvantage of forming an acoustic wave resonator 30 with a multiplayer piezoelectric substrate as illustrated in FIG. 2 is that an interface between the upper surface of the Si carrier substrate 36 and the lower surface of the dielectric material layer 34 may include parasitic surface charges that may cause the resonator to exhibit a lower quality factor Q than desirable due to losses caused by parasitic surface conductivity associated with the parasitic surface charges. This undesirable effect may be at least partially alleviated by forming a trap rich layer 42, for example, a layer of polysilicon in the upper portion of the Si carrier substrate 36 as illustrated in FIG. 3. The addition of the trap-rich layer 42, however, involves additional processing steps which may be more expensive than desired.

Desired figures of merit for multilayer piezoelectric substrate acoustic wave resonators include high quality factor Q, high electromechanical coupling coefficient kₜ², and high power durability as well as favorable large signal performance characteristics such as low intermodulation distortion, low amplitude of high order harmonics (e.g., H2 or H3 harmonics), and low non-linearity. In some embodiments, filters formed from multilayer piezoelectric substrate acoustic wave resonators may include one or more stages including cascaded resonators to help reduce performance non-linearities. The inclusion of cascaded resonators, however, may undesirably increase the overall size of an acoustic wave filter or a die upon which the filter is formed.

Applicants have discovered that performance linearity of a SAW resonator including a multilayer piezoelectric substrate as illustrated in FIG. 3 may be improved to reduce the magnitude of H2 and/or H3 harmonics by a number of methods which may be utilized individually or in combination.

Applicants have discovered that the magnitude of H2 and H3 harmonics generated during operation of a SAW resonator including a multilayer piezoelectric substrate as illustrated in FIG. 3 is affected by the thickness of the dielectric material (e.g., silicon dioxide) layer 34 and/or the carrier substrate 36 and/or the trap rich layer 42. Accordingly, one may select thicknesses of the trap-rich (e.g., polysilicon) layer 42 and/or the dielectric material (e.g., silicon dioxide) layer 34 and/or carrier substrate 36 to achieve a desired degree of linearity in terms of low magnitude/amplitude of H2 and/or H3 harmonic signals. For example, in some embodiments, the H2/H3 harmonics peak can be minimized by tuning the dielectric material layer 34 thickness between 1~3 µm, depending on the frequency at which the H2/H3 peak is located at. The trap-rich layer 42 below the dielectric material layer 34 may have a thickness of about 1 µm.

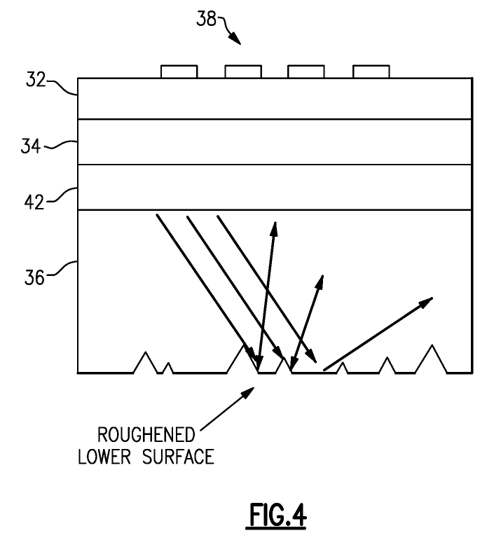

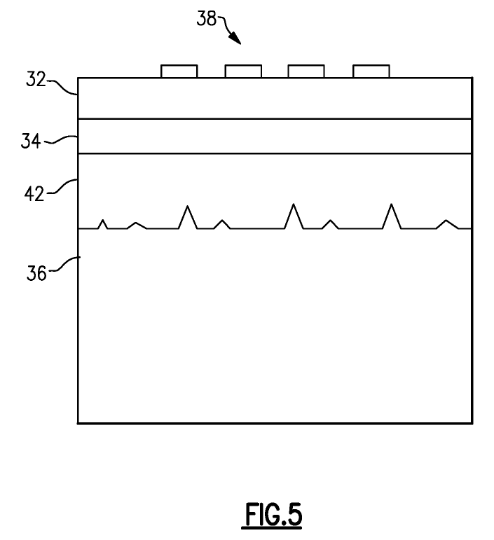

Additionally or alternatively to selecting thicknesses of the layers 34, 36, and/or 42 to mitigate the generation of H2 and/or H3 harmonic signals, one may roughen the lower surface of the carrier substrate. The roughened lower surface of the carrier substrate 36 may scatter nonlinear H2 and/or H3 signals, for example, as illustrated in FIG. 4. The lower surface of the carrier substrate 36 may be roughened using chemical mechanical polishing or other known methods to a roughness of, for example, Rₐ ≥ 0.2 µm. Similar scattering of H2 and/or H3 harmonic signals may be achieved by roughening the bottom side of the trap-rich (e.g., polysilicon) layer 42 as shown in FIG. 5. The bottom side of the trap-rich layer 42 may be roughened using chemical mechanical polishing or other known methods to a roughness of, for example, Rₐ ≥ 0.2 µm. Additionally or alternatively, one may apply a damping material 44, for example, a soft sheet, adhesive tape, a layer of polymer such as polyimide, or molding compound with fillers to the lower surface of the carrier substrate as illustrated in FIG. 6 to absorb spurious H2 and/or H3 signals that may impinge upon the lower surface of the carrier substrate.

By modifying a SAW resonator with a multilayer piezoelectric substrate in any one or more of the methods described above good linearity performance may be achieved. A filter formed from one or more multilayer piezoelectric substrate surface acoustic wave resonators including one or more of these features may exhibit favorable linearity without the need for utilizing cascaded resonators, which may provide for a small overall size of the filter or die in which the filter is formed.

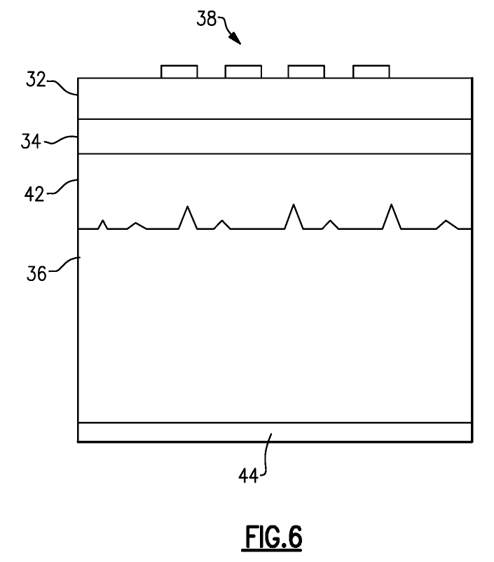

In some embodiments, multiple SAW resonators as disclosed herein may be combined into a filter, for example, an RF ladder filter schematically illustrated in FIG. 7 and including a plurality of series resonators R1,R3,R5,R7, and R9, and a plurality of parallel (or shunt) resonators R2, R4, R6, and R8. As shown, the plurality of series resonators R1,R3,R5,R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

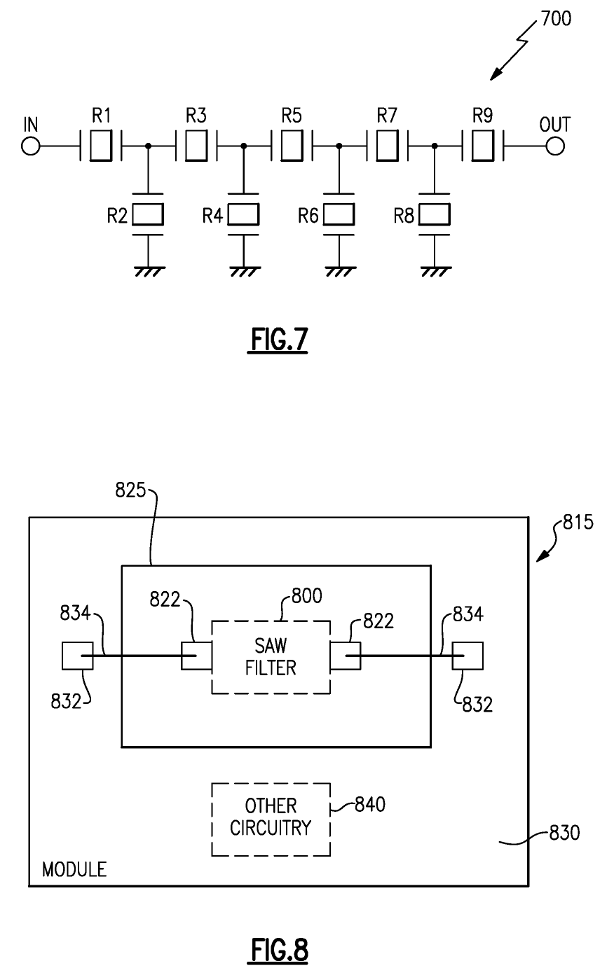

Examples of the SAW devices, e.g., SAW resonators discussed herein can be implemented in a variety of packaged modules. Some example packaged modules will now be discussed in which any suitable principles and advantages of the SAW devices discussed herein can be implemented. FIGS. 8, 9, and FIG. 10 are schematic block diagrams of illustrative packaged modules and devices according to certain embodiments.

As discussed above, surface acoustic wave resonators can be used in surface acoustic wave (SAW) RF filters. In turn, a SAW RF filter using one or more surface acoustic wave elements may be incorporated into and packaged as a module that may ultimately be used in an electronic device, such as a wireless communications device, for example. FIG. 8 is a block diagram illustrating one example of a module 815 including a SAW filter 800. The SAW filter 800 may be implemented on one or more die(s) 825 including one or more connection pads 822. For example, the SAW filter 800 may include a connection pad 822 that corresponds to an input contact for the SAW filter and another connection pad 822 that corresponds to an output contact for the SAW filter. The packaged module 815 includes a packaging substrate 830 that is configured to receive a plurality of components, including the die 825. A plurality of connection pads 832 can be disposed on the packaging substrate 830, and the various connection pads 822 of the SAW filter die 825 can be connected to the connection pads 832 on the packaging substrate 830 via electrical connectors 834, which can be solder bumps or wirebonds, for example, to allow for passing of various signals to and from the SAW filter 800. The module 815 may optionally further include other circuitry die 840, for example, one or more additional filter(s), amplifiers, pre-filters, modulators, demodulators, down converters, and the like, as would be known to one of skill in the art of semiconductor fabrication in view of the disclosure herein. In some embodiments, the module 815 can also include one or more packaging structures to, for example, provide protection and facilitate easier handling of the module 815. Such a packaging structure can include an overmold formed over the packaging substrate 830 and dimensioned to substantially encapsulate the various circuits and components thereon.

Various examples and embodiments of the SAW filter 800 can be used in a wide variety of electronic devices. For example, the SAW filter 800 can be used in an antenna duplexer, which itself can be incorporated into a variety of electronic devices, such as RF front-end modules and communication devices.

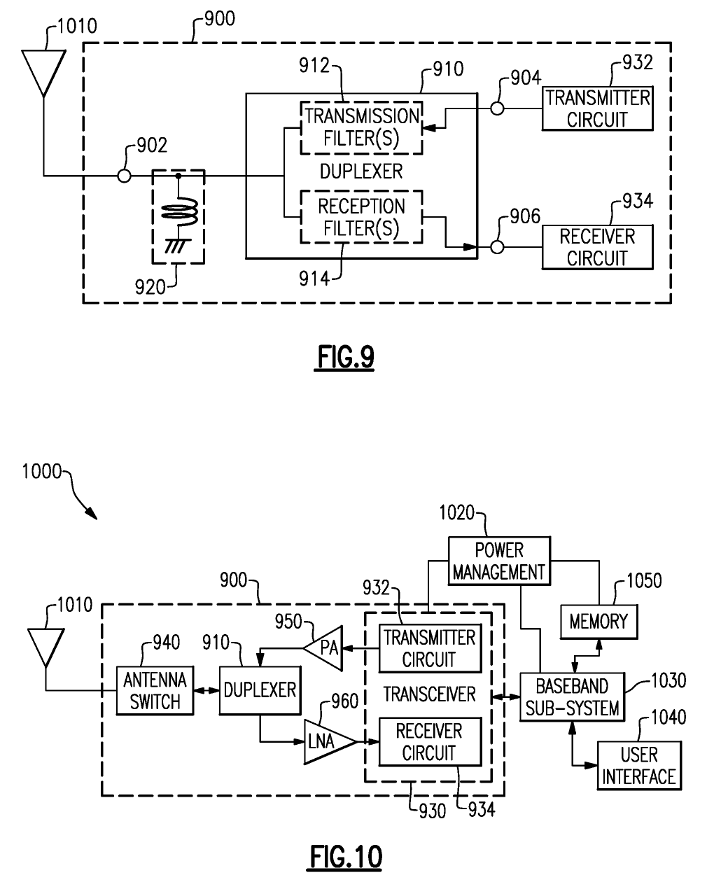

Referring to FIG. 9, there is illustrated a block diagram of one example of a front-end module 900, which may be used in an electronic device such as a wireless communications device (e.g., a mobile phone) for example. The front-end module 900 includes an antenna duplexer 910 having a common node 902, an input node 904, and an output node 906. An antenna 1010 is connected to the common node 902.

The antenna duplexer 910 may include one or more transmission filters 912 connected between the input node 904 and the common node 902, and one or more reception filters 914 connected between the common node 902 and the output node 906. The passband(s) of the transmission filter(s) are different from the passband(s) of the reception filters. Examples of the SAW filter 800 can be used to form the transmission filter(s) 912 and/or the reception filter(s) 914. An inductor or other matching component 920 may be connected at the common node 902.

The front-end module 900 further includes a transmitter circuit 932 connected to the input node 904 of the duplexer 910 and a receiver circuit 934 connected to the output node 906 of the duplexer 910. The transmitter circuit 932 can generate signals for transmission via the antenna 1010, and the receiver circuit 934 can receive and process signals received via the antenna 1010. In some embodiments, the receiver and transmitter circuits are implemented as separate components, as shown in FIG. 9, however, in other embodiments these components may be integrated into a common transceiver circuit or module. As will be appreciated by those skilled in the art, the front-end module 900 may include other components that are not illustrated in FIG. 9 including, but not limited to, switches, electromagnetic couplers, amplifiers, processors, and the like.

FIG. 10 is a block diagram of one example of a wireless device 1000 including the antenna duplexer 910 shown in FIG. 9. The wireless device 1000 can be a cellular phone, smart phone, tablet, modem, communication network or any other portable or non-portable device configured for voice or data communication. The wireless device 1000 can receive and transmit signals from the antenna 1010. The wireless device includes an embodiment of a front-end module 900 similar to that discussed above with reference to FIG. 9. The front-end module 900 includes the duplexer 910, as discussed above. In the example shown in FIG. 10 the front-end module 900 further includes an antenna switch 940, which can be configured to switch between different frequency bands or modes, such as transmit and receive modes, for example. In the example illustrated in FIG. 10, the antenna switch 940 is positioned between the duplexer 910 and the antenna 1010; however, in other examples the duplexer 910 can be positioned between the antenna switch 940 and the antenna 1010. In other examples the antenna switch 940 and the duplexer 910 can be integrated into a single component.

The front-end module 900 includes a transceiver 930 that is configured to generate signals for transmission or to process received signals. The transceiver 930 can include the transmitter circuit 932, which can be connected to the input node 904 of the duplexer 910, and the receiver circuit 934, which can be connected to the output node 906 of the duplexer 910, as shown in the example of FIG. 10.

Signals generated for transmission by the transmitter circuit 932 are received by a power amplifier (PA) module 950, which amplifies the generated signals from the transceiver 930. The power amplifier module 950 can include one or more power amplifiers. The power amplifier module 950 can be used to amplify a wide variety of RF or other frequency-band transmission signals. For example, the power amplifier module 950 can receive an enable signal that can be used to pulse the output of the power amplifier to aid in transmitting a wireless local area network (WLAN) signal or any other suitable pulsed signal. The power amplifier module 950 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 950 and associated components including switches and the like can be fabricated on gallium arsenide (GaAs) substrates using, for example, high-electron mobility transistors (pHEMT) or insulated-gate bipolar transistors (BiFET), or on a silicon substrate using complementary metal-oxide semiconductor (CMOS) field effect transistors.

Still referring to FIG. 10, the front-end module 900 may further include a low noise amplifier module 960, which amplifies received signals from the antenna 1010 and provides the amplified signals to the receiver circuit 934 of the transceiver 930.

The wireless device 1000 of FIG. 10 further includes a power management sub-system 1020 that is connected to the transceiver 930 and manages the power for the operation of the wireless device 1000. The power management sub-system 1020 can also control the operation of a baseband sub-system 1030 and various other components of the wireless device 1000. The power management sub-system 1020 can include, or can be connected to, a battery (not shown) that supplies power for the various components of the wireless device 1000. The power management sub-system 1020 can further include one or more processors or controllers that can control the transmission of signals, for example. In one embodiment, the baseband sub-system 1030 is connected to a user interface 1040 to facilitate various input and output of voice and/or data provided to and received from the user. The baseband sub-system 1030 can also be connected to memory 1050 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave resonator including a multilayer piezoelectric substrate comprising:
a carrier substrate having an upper surface and a lower surface;
a trap-rich layer having an upper surface and a lower surface, the lower surface of the trap-rich layer disposed on the upper surface of the carrier substrate;
a low acoustic velocity dielectric layer having an upper surface and a lower surface, the lower surface of the low acoustic velocity dielectric layer disposed on the upper surface of the trap-rich layer; and
a layer of piezoelectric material having an upper surface and a lower surface, the lower surface of the layer of piezoelectric material disposed on the upper surface of the low acoustic velocity dielectric layer, a thickness of one or more of the carrier substrate, the trap-rich layer, or the low acoustic velocity dielectric layer selected to mitigate H2 and/or H3 spurious signals generated during operation of the surface acoustic wave resonator.

2. The surface acoustic wave resonator of claim 1 wherein the lower surface of the carrier substrate is roughened.

3. The surface acoustic wave resonator of claim 2 wherein the lower surface of the carrier substrate has a roughness parameter Rₐ≥ 0.2 µm.

4. The surface acoustic wave resonator of claim 1 wherein the lower surface of the trap-rich layer is roughened.

5. The surface acoustic wave resonator of claim 4 wherein the lower surface of the trap-rich layer has a roughness parameter Rₐ≥ 0.2 µm.

6. The surface acoustic wave resonator of claim 1 further comprising a layer of damping material disposed on the lower surface of the carrier substrate.

7. The surface acoustic wave resonator of claim 1 wherein the low acoustic velocity dielectric layer comprises silicon dioxide.

8. The surface acoustic wave resonator of claim 1 wherein the trap-rich layer comprises polysilicon.

9. The surface acoustic wave resonator of claim 1 wherein the low acoustic velocity dielectric layer has a thickness of between 1 µm and 3 µm.

10. The surface acoustic wave resonator of claim 1 wherein the trap-rich layer has a thickness of about 1 µm.

11. A filter including the surface acoustic wave resonator of claim 10.

12. A radio frequency device module including the filter of claim 11.

13. A radio frequency device including the radio frequency device module of claim 12.

14. A method of forming a surface acoustic wave resonator, the method comprising:
providing a carrier substrate having an upper surface and a lower surface;
forming a trap-rich layer on the upper surface of the carrier substrate;
forming a low acoustic velocity dielectric layer on an upper surface of trap-rich layer;
forming a layer of piezoelectric material on an upper surface of the low acoustic velocity dielectric layer; and
forming interdigital transducer electrodes on an upper surface of the layer of piezoelectric material, a thickness of one or more of the carrier substrate, the trap-rich layer, or the low acoustic velocity dielectric layer selected to mitigate H2 and/or H3 spurious signals generated during operation of the surface acoustic wave resonator.

15. The method of claim 14 further comprising roughening the lower surface of the carrier substrate.

16. The method of claim 14 further comprising roughening a lower surface of the trap-rich layer.

17. The method of claim 14 further comprising forming a layer of damping material on the lower surface of the carrier substrate.

18. The method of claim 14 further comprising forming a radio frequency filter including the surface acoustic wave resonator of claim 14.

19. The method of claim 18 further comprising forming a radio frequency device module including the radio frequency filter of claim 18.

20. The method of claim 19 further comprising forming a radio frequency electronic device including the radio frequency device module of claim 19.
